(19) United States
(12) Patent Application Publication
(10) Pub. No.: US 2006/0214163 A1
(43) Pub. Date: Sep. 28, 2006

(54) Stressed organic semiconductor

(76) Inventors: Kiyotaka Mori, Arlington, MA (US); Daniel Hogan, Acton, MA (US)

Correspondence Address: RATNERPRESTIA, P.O. BOX 980, VALLEY FORGE, PA, 19482, US

(21) Appl. No.: 11/441,364

(22) Filed: May 25, 2006

Related U.S. Application Data
(62) Division of application No. 10/807,065, filed on Mar. 23, 2004.

(51) Int. Cl. H01L 29/08; H01L 21/00

(52) U.S. Cl. 257/40; 438/82

(57) ABSTRACT

A semiconductor device including: a substrate and an organic semiconductor material coupled to the substrate at an interface therebetween. The substrate has a first thermal expansion coefficient and the organic semiconductor material has a second thermal expansion coefficient that is different from the first thermal expansion coefficient. The difference between the first thermal expansion coefficient and the second thermal expansion coefficient causes a tensile stress in a plane parallel to the interface to be transferred from the substrate to the organic semiconductor material through the interface. This tensile stress in the plane parallel to the interface causes compression of the organic semiconductor material in a direction normal to the interface.

### CROSS-REFERENCE TO RELATED APPLICATIONS

This application is a divisional of U.S. application Ser. No. 10/807,065, filed Mar. 23, 2004, the contents of which is incorporated herein by reference.

### FIELD OF THE INVENTION

The present invention relates generally to organic semiconductor devices and, more particularly, to varying charge carrier mobility in organic semiconductor devices.

### BACKGROUND OF THE INVENTION

Semiconductor-based devices and systems conventionally utilize inorganic semiconductor materials, for example, silicon-based materials. Organic semiconductors have the potential to replace conventional inorganic semiconductors in a number of applications, and further may provide additional applications to which inorganic semiconductors have not been utilized. Such applications may include, for example, display systems, mobile devices, sensor systems, computing devices, signal reception devices, signal transmission devices, and memory devices.

Unfortunately, organic semiconductors often have inefficient charge carrier mobility in contrast to inorganic semiconductors. The source of this inefficiency is that the electrical properties of organic semiconductors are largely limited by intrinsic material properties. Such properties include, for example, morphology, crystallinity, and packing density of molecules.

Prior attempts to increase charge carrier mobility in organic semiconductors have proven inadequate. Therefore, a need exists for a method of efficiently increasing or decreasing charge carrier mobility in organic semiconductors.

### SUMMARY OF THE INVENTION

To meet this and other needs, and in view of its purposes, the present invention provides a semiconductor device. In a first exemplary embodiment, the semiconductor device includes a substrate having a first thermal expansion coefficient and an organic semiconductor material coupled to the substrate at an interface between the substrate and the organic semiconductor material. The organic semiconductor material has a second thermal expansion coefficient that is different from the first thermal expansion coefficient. A mechanical stress is transferred from the substrate to the organic semiconductor through the interface. The mechanical stress is related to the difference between the first thermal expansion coefficient and the second thermal expansion coefficient.

According to another exemplary embodiment of the present invention, a method of fabricating a semiconductor device is provided. The method includes providing a substrate having a first thermal expansion coefficient. The method also includes coupling an organic semiconductor material to the substrate at an interface between the substrate and the organic semiconductor material. The organic semiconductor material has a second thermal expansion coefficient that is different from the first thermal expansion coefficient. The method also includes applying a mechanical stress to the organic semiconductor material through the interface by varying a temperature of the substrate such that the substrate changes in at least one physical dimension. As utilized in this document, the expression “varying a temperature” may refer to an intentional variation in temperature (e.g., heating or cooling) or may refer to normalization to an environmental or ambient temperature from a temperature above or below the ambient temperature.

According to yet another exemplary embodiment of the present invention, a semiconductor device is provided. The semiconductor device includes a substrate and an organic semiconductor material coupled to the substrate at an interface between the substrate and the organic semiconductor material. The semiconductor device also includes an actuator provided for use with at least one of the substrate or the organic semiconductor material. The actuator is selected from the group comprising piezoelectric actuators, piezomagnetic actuators, electrostrictive actuators, magnetostrictive actuators, electrostatic actuators, magnetostatic actuators, shape memory alloy actuators, magnetic shape memory alloy actuators, and electroactive polymer actuators. The actuator applies a mechanical force to at least one of the substrate or the organic semiconductor material upon the actuator being actuated. The mechanical force applied by the actuator varies a carrier mobility of the organic semiconductor material.

According to yet another exemplary embodiment of the present invention, a method of fabricating a semiconductor device is provided. The method includes providing an organic semiconductor material coupled to a substrate. The method also includes providing an actuator for use with at least one of the substrate or the organic semiconductor material. The actuator is selected from the group comprising piezoelectric actuators, piezomagnetic actuators, electrostrictive actuators, magnetostrictive actuators, electrostatic actuators, magnetostatic actuators, shape memory alloy actuators, magnetic shape memory alloy actuators, and electroactive polymer actuators. The method also includes applying a mechanical force to at least one of the substrate or the organic semiconductor material by actuating the actuator. The mechanical force applied by actuating the actuator varies a carrier mobility of the organic semiconductor material.

According to yet another exemplary embodiment of the present invention, a semiconductor device is provided. The semiconductor device includes a semiconductor package and an organic semiconductor material provided within the semiconductor package. The semiconductor package has a hydrostatic pressure applied to it such that the pressure within the semiconductor package is different from atmospheric pressure. The applied hydrostatic pressure varies a carrier mobility of the organic semiconductor material.

According to yet another exemplary embodiment of the present invention, a method of fabricating a semiconductor device is provided. The method includes providing an organic semiconductor material in a semiconductor package. The method also includes applying a hydrostatic pressure to the semiconductor package such that the pressure within the semiconductor package is different from atmospheric pressure. The applied hydrostatic pressure varies a carrier mobility of the organic semiconductor material.

It is to be understood that both the foregoing general description and the following detailed description are exemplary, but are not restrictive, of the invention.

### BRIEF DESCRIPTION OF THE DRAWING

Exemplary embodiments of the invention are best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1 is a block diagram of a semiconductor device in accordance with an exemplary embodiment of the present invention;

FIG. 2 is a block diagram of another semiconductor device in accordance with another exemplary embodiment of the present invention;

FIG. 3 is a block diagram of a semiconductor device during various phases of fabrication in accordance with an exemplary embodiment of the present invention;

FIGS. 4A, 4B, and 4C are representations of carrier mobility in various configurations in accordance with exemplary embodiments of the present invention;

FIGS. 5A, 5B, and 5C are block diagrams of semiconductor devices including an actuator in accordance with exemplary embodiments of the present invention;

FIG. 6 is a block diagram of a packaged semiconductor device in accordance with an exemplary embodiment of the present invention;

FIG. 7 is a flow diagram illustrating a method of fabricating a semiconductor device in accordance with an exemplary embodiment of the present invention;

FIG. 8 is a flow diagram illustrating another method of fabricating a semiconductor device in accordance with another exemplary embodiment of the present invention; and

FIG. 9 is a flow diagram illustrating yet another method of fabricating a semiconductor device in accordance with another exemplary embodiment of the present invention.

### DETAILED DESCRIPTION OF THE INVENTION

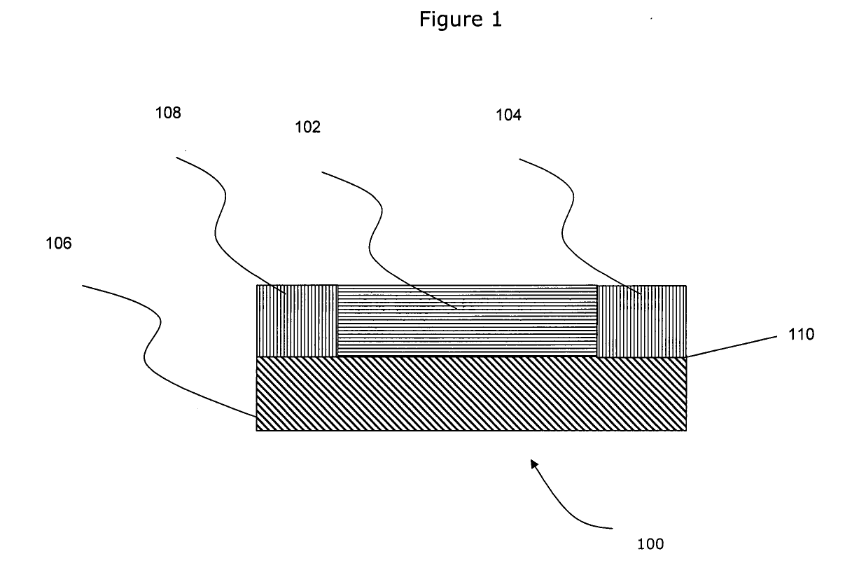

Preferred features of embodiments of the present invention will now be described with reference to the figures. It will be appreciated that the spirit and scope of the invention is not limited to the embodiments selected for illustration. FIG. 1 illustrates a semiconductor device 100 which includes an organic semiconductor 102 supported by a substrate 106. Semiconductor device 100 also includes electrodes 104 and 108. During operation, current flows from one electrode (e.g., the drain in the case of a transistor) to the other (e.g., the source in the case of transistor). As will be explained, semiconductor device 100 is formed such that a stress is applied to organic semiconductor 102 through a mechanical interaction occurring at the interface 110 between organic semiconductor 102 and substrate 106.

More specifically, the mechanical interaction relates to a change in a dimension of substrate 106 (e.g., a change in a dimension that is parallel to interface 110) that results in a corresponding change in a dimension of organic semiconductor 102. For example, the mechanical interaction in the lateral structure illustrated in FIG. 1 is related to a decrease in a dimension of substrate 106 that results in a compressive stress being applied to organic semiconductor 102. This compressive stress leads to negative strain in organic semiconductor 102, resulting in an increase in carrier mobility (e.g., electron or hole mobility) in organic semiconductor 102.

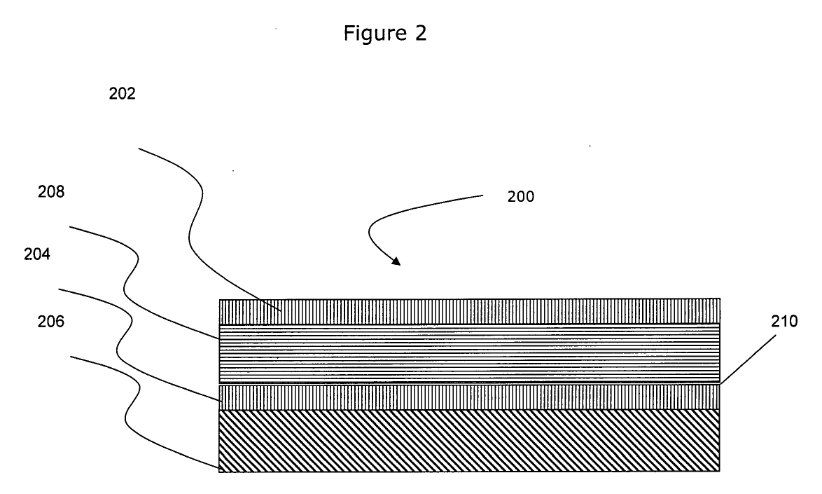

FIG. 2 illustrates a vertically structured semiconductor device 200 which includes an organic semiconductor 208 supported by a substrate 206. Semiconductor device 200 also includes electrodes 202 and 204. Electrode 204 is positioned between substrate 206 and organic semiconductor 208. Similar to semiconductor device 100 illustrated in FIG. 1, semiconductor device 200 is formed such that a stress is applied to organic semiconductor 208 through a mechanical interaction occurring at the interface 210 between organic semiconductor 208 and substrate 206.

More specifically, the mechanical interaction relates to a change in a dimension of substrate 206 (e.g., elongation of substrate 206 in a direction that is parallel to interface 210) that results in a corresponding change in a dimension of organic semiconductor 208. Such an elongation of substrate 206 induces a negative strain in organic semiconductor 208 in the direction of current flow, resulting in an increase in carrier mobility (e.g., electron or hole mobility) in organic semiconductor 208. Interestingly, the mechanical interaction that ultimately results in the increase in electron mobility occurs even though organic semiconductor 208 is not in direct contact with substrate 206 (i.e., electrode 204 is positioned between substrate 206 and organic semiconductor 208).

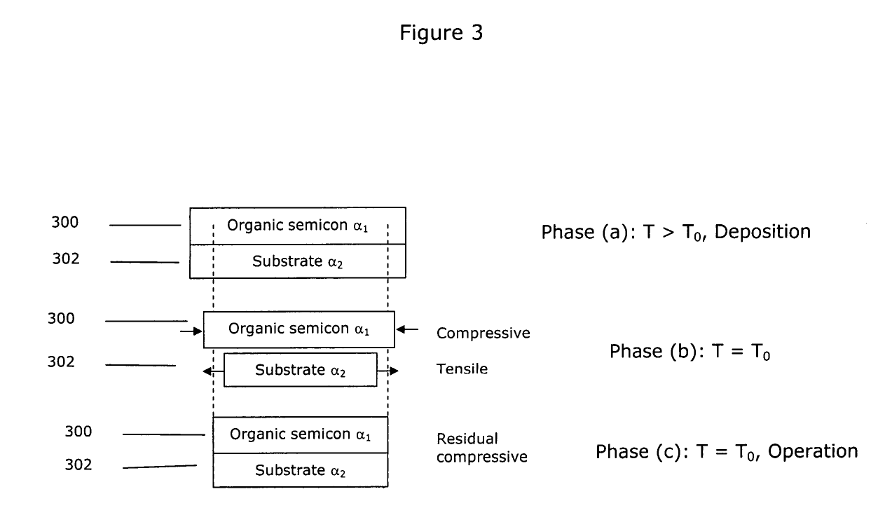

The various exemplary embodiments of the present invention provide a number of methods of affecting carrier (e.g., electron) mobility in an organic semiconductor through a dimensional change to a substrate. For example, FIG. 3 illustrates the use of differing thermal expansion coefficients for each of a substrate and an organic semiconductor in order to impact electron mobility of the organic semiconductor. During a first phase (i.e., phase “(a)”), an organic semiconductor 300 is provided on a substrate 302. Organic semiconductor 300 has a thermal expansion coefficient α₁ and substrate 302 has a thermal expansion coefficient α₂. During this first phase (i.e., the deposition phase, where organic semiconductor 300 is deposited and/or annealed on substrate 302), the temperature of organic semiconductor 300 and substrate 302 is T, which is greater than T₀. T₀ is the temperature at which the organic semiconductor device is operated (e.g., room temperature, ambient temperature, etc.).

Moving now to the second phase (i.e., phase “(b)”) illustrated in FIG. 3, the actual temperature T has cooled to T₀. Assuming that the thermal expansion coefficient α₂ of substrate 302 is higher than the thermal expansion coefficient α₁ of organic semiconductor 300, substrate 302 shrinks more than organic semiconductor 300 when cooled down to T₀. This situation is visually represented in that substrate 302 is illustrated as being laterally smaller than organic semiconductor 300 in the second phase of FIG. 3. Because substrate 302 shrinks more than organic semiconductor 300 during this second phase, a tensile stress in substrate 302 and a corresponding compressive stress is applied to keep the two components (i.e., substrate 302 and organic semiconductor 300) at the same dimension, attached at the interface.

At the third phase (i.e., phase “(c)”) illustrated in FIG. 3, the device (including organic semiconductor 300 and substrate 302) is prepared for operation at temperature T₀. At this third phase, the device has reached an equilibrium state where a residual compressive stress is present in organic semiconductor 300. This residual compressive stress (and corresponding strain) desirably results in increased carrier mobility in organic semiconductor 300.

In the exemplary embodiment of the present invention illustrated in FIG. 3, the compressive strain in organic semiconductor 300 in the third phase may be defined as Δα ΔT, where Δα is the difference in the thermal expansion coefficients of organic semiconductor 300 and substrate 302 and ΔT is the temperature difference between T and T₀. Assuming Δα is 10 ppm/degree C. and ΔT is 100 degrees C., the compressive strain is 1000 ppm (i.e., 0.1%). Assuming a modulus of organic semiconductor 300 to be in the range between 1 GPa and 1000 GPa, the compressive stress applied to organic semiconductor 300 is then between 1 MPa and 1000 MPa. This provides increases in mobility by a factor of between 0.01 to 10.

According to another exemplary embodiment of the present invention, a substrate may be used that has a lower thermal expansion coefficient (i.e., TEC) than the organic semiconductor, and the organic semiconductor (e.g., an organic semiconductor film) may be deposited at a temperature that is lower than the operational temperature. According to this embodiment, improved electron mobility in the organic semiconductor is achieved.

According to another exemplary embodiment of the present invention, the techniques disclosed in this document (including the use of thermal expansion coefficients affecting the dimension of the substrate as described above) may be used to apply a tensile stress (as opposed to a compressive stress) to an organic semiconductor. Such an embodiment may be useful in reducing electron mobility of the organic semiconductor.

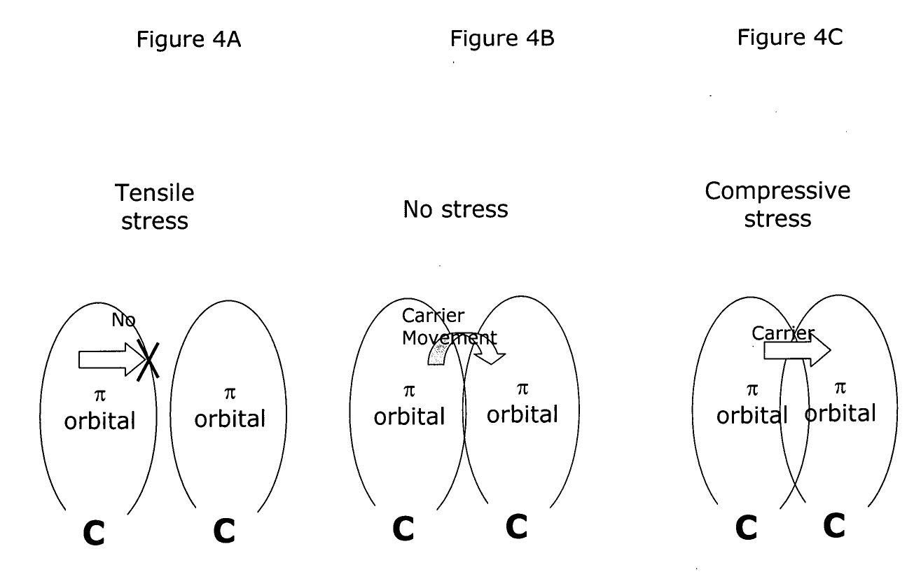

FIGS. 4A, 4B, and 4C are illustrations of carrier mobility (e.g., electron mobility) in a carbon-based organic semiconductor molecule, where adjacent pi (π) electron orbitals are shown. As illustrated in FIGS. 4A, 4B, and 4C, the shorter the distance between adjacent molecules, the easier it is to transfer charge carriers (e.g., electrons) between the adjacent molecules. In FIG. 4A, a tensile stress is intentionally applied to the organic semiconductor; therefore, carrier mobility is substantially reduced. FIG. 4B represents the state of the organic semiconductor without application of tensile or compressive stress. Carriers move (e.g., hop, tunnel, etc.) from one pi electron orbital to the adjacent orbital. In FIG. 4C, a compressive stress is intentionally applied to the organic semiconductor; therefore, carriers transfer from one pi orbital to an adjacent pi orbital because of the increased mobility.

Thus, as illustrated by FIGS. 4A, 4B, and 4C, the electron mobility of the organic semiconductor may be enhanced by increasing the overlap of pi electron orbitals of the organic semiconductor's molecules (i.e., as shown in FIG. 4C). This increase of overlap may be described as pi-pi stacking of molecules of the organic semiconductor. Thus, according to certain exemplary embodiments of the present invention, compressive stress is applied to the organic semiconductor to enhance overlapping of pi electron orbitals.

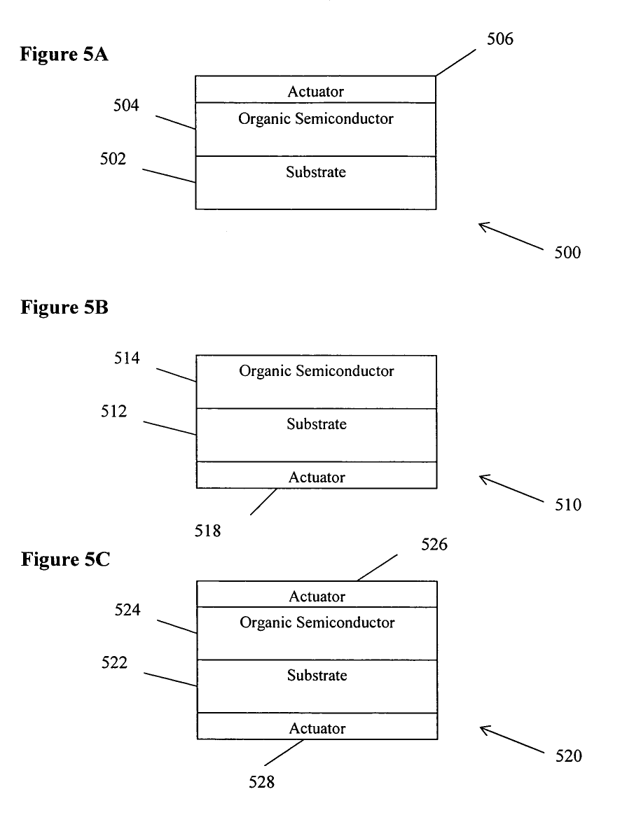

Certain embodiments of the present invention use actuators (or actuator materials) to vary carrier mobility in an organic semiconductor material. Such actuators include, for example, piezoelectric actuators (i.e., materials generating a mechanical force when a voltage is applied, as in a piezoelectric crystal), piezomagnetic actuators (i.e., materials generating a mechanical force when a magnetic field is applied), electrostrictive actuators (i.e., materials generating a mechanical force when a voltage is applied, as in an electrostrictive crystal such as PMN-PT), magnetostrictive actuators (i.e., materials exhibiting a change in dimension when placed in a magnetic field, also known as the Joule effect), electrostatic actuators (i.e., actuator or material generating an electrostatic force when a voltage is applied), magnetostatic actuators (i.e., actuator generating a mechanical force between two magnetic poles), shape memory alloy actuators (i.e., if the material (e.g., a film) is deformed at a low temperature, upon heating the material will exert a high force to re-attain its as-deposited shape), magnetic shape memory alloy actuators (i.e., smart materials which can undergo large reversible deformations in an applied magnetic field to function as actuators, and compared to ordinary temperature driven shape memory alloys, the magnetic control offers faster response, as the heating and cooling is slower than applying the magnetic field), and electroactive polymer actuators (i.e., a polymer which responds to external electrical stimulation by displaying a significant shape or size displacement). Such actuators may be used to provide a broad range of desired strain values to organic semiconductors (e.g., strain values ranging from 0.1-400%). The actuator may be independent of the substrate or the organic semiconductor as illustrated and described below with reference to FIGS. 5A, 5B, and 5C, or the actuator may be integrated into at least one of the substrate or the organic semiconductor.

FIG. 5A is a block diagram of a semiconductor device 500. Semiconductor device 500 includes an organic semiconductor 504 mounted on a substrate 502. An actuator 506 is provided on organic semiconductor 504. For example, actuator 506 may be a piezoelectric actuator. In such an embodiment, upon application of a predetermined voltage to piezoelectric actuator 506, a dimension of piezoelectric actuator 506 changes (e.g., piezoelectric actuator 506 shrinks). This dimensional change in piezoelectric actuator 506 results in the application of a mechanical force at the interface between piezoelectric actuator 506 and organic semiconductor 504. For example, this mechanical force may be a stress or strain applied to organic semiconductor 504 that changes the carrier mobility of organic semiconductor 504 as described above, for example, with respect to FIG. 1. Of course, a piezoelectric actuator is simply an example of a type of actuator 506, and any of a number of alternative actuating materials or mechanisms may be utilized so long as the actuator results in the application of the desired mechanical force (e.g., stress, strain, etc.) at the interface between actuator 506 and organic semiconductor 504.

FIG. 5B is a block diagram of a semiconductor device 510. Semiconductor device 510 includes an organic semiconductor 514 mounted on a substrate 512. An actuator 518 is provided below substrate 512. For example, actuator 518 may be a piezomagnetic actuator. In such an embodiment, upon application of a predetermined magnetic field to piezomagnetic actuator 518, a dimension of piezomagnetic actuator 518 changes (e.g., piezomagnetic actuator 518 shrinks) (a predetermined magnetic field is a field that is reasonably predictable, as opposed to random, before it is applied). This dimensional change in piezomagnetic actuator 518 results in the application of a mechanical force at the interface between piezomagnetic actuator 518 and substrate 512.

For example, this mechanical force may be a stress or strain applied to substrate 512. This stress or strain is transferred through substrate 512 to the interface between substrate 512 and organic semiconductor 514. This stress or strain is applied to organic semiconductor 514 through the interface between substrate 512 and organic semiconductor 514, and changes the carrier mobility of organic semiconductor 514. Of course, a piezomagnetic actuator is simply an example of a type of actuator 518, and any of a number of alternative actuating materials or mechanisms may be utilized so long as the actuator results in the application of the desired mechanical force (e.g., stress, strain, etc.) through substrate 512 and to the interface between substrate 512 and organic semiconductor 514.

FIG. 5C is a block diagram of a semiconductor device 520. Semiconductor device 520 includes an organic semiconductor 524 mounted on a substrate 522. An actuator 526 is provided on organic semiconductor 524. Further, an actuator 528 is provided below substrate 522. For example, actuators 526 and 528 may be piezoelectric actuators. In such an embodiment, upon application of a predetermined voltage to piezoelectric actuator 526, a dimension of piezoelectric actuator 526 changes (e.g., piezoelectric actuator 526 shrinks). This dimensional change in piezoelectric actuator 526 results in the application of a mechanical force at the interface between piezoelectric actuator 526 and organic semiconductor 524. For example, this mechanical force may be a stress or strain applied to organic semiconductor 524 that changes the carrier mobility of organic semiconductor 524, as described above.

Further, upon application of a predetermined voltage to piezoelectric actuator 528, a dimension of piezoelectric actuator 528 changes (e.g., piezoelectric actuator 528 shrinks). This dimensional change in piezoelectric actuator 528 results in the application of a mechanical force at the interface between piezoelectric actuator 528 and substrate 522. For example, this mechanical force may be a stress or strain applied to substrate 522. This stress or strain is transferred through substrate 522 to the interface between substrate 522 and organic semiconductor 524. This stress or strain is applied to organic semiconductor 524 through the interface between substrate 522 and organic semiconductor 524, and changes the carrier mobility of organic semiconductor 524.

Thus, in the exemplary embodiment of the present invention illustrated in FIG. 5C, carrier mobility of organic semiconductor 524 is altered through the use of actuator 526 and actuator 528.

According to certain other exemplary embodiments of the present invention, the actuator (e.g., piezoelectric actuator, piezomagnetic actuator, and the like) may actually be integrated into at least one of an organic semiconductor or a substrate on which the organic semiconductor is mounted. For example, if an organic semiconductor is mounted on a substrate including a piezoelectric material, then the carrier mobility of the organic semiconductor may be altered by applying a predetermined voltage to the substrate. Similarly, if an organic semiconductor is mounted on a substrate where the organic semiconductor includes a piezomagnetic material, then the carrier mobility of the organic semiconductor may be altered by applying a predetermined magnetic field to the organic semiconductor. Further still, if an organic semiconductor is mounted on a substrate where both the organic semiconductor and the substrate include a piezoelectric material, then the carrier mobility of the organic semiconductor may be altered by applying a predetermined electric field to the organic semiconductor, the substrate, or both.

Although the exemplary embodiments of the present invention depicted in FIGS. 5A, 5B, and 5C illustrate semiconductor devices including only substrates, organic semiconductors, and actuators, it is clear that these and other semiconductor devices described in this document may include a number of other features. For example, the semiconductor materials may include terminals (e.g., two-terminal devices, three-terminal devices, multi-terminal devices, etc.), electrodes, insulating film layers, and other elements (e.g., gate insulator, gate electrode, etc.). In an embodiment utilizing a piezoelectric actuator, such insulation layers may be provided to isolate the applied voltage to the actuator, thereby protecting against potential short-circuiting.

The various exemplary embodiments of the present invention using actuators primarily relate to actuators that (either directly or through a mechanical interaction with a substrate) alter the carrier mobility of an organic semiconductor through actuation of the actuator; however, the reverse process is also contemplated. More specifically, an actuator may be de-actuated (e.g., the magnetic field removed in the case of a piezomagnetic actuator) in order to cause the mechanical interaction (e.g., change in dimension of the substrate and/or organic semiconductor) that varies the carrier mobility of the organic semiconductor. Thus, the application of a mechanical force to at least one of the substrate or the organic semiconductor upon the actuator being actuated (where the mechanical force varies a carrier mobility of the organic semiconductor) may be through a positive actuation of the actuator (e.g., application of a magnetic field in the case of a piezomagnetic actuator) or a negative actuation of the actuator (e.g., removal of a magnetic field in the case of a piezomagnetic actuator).

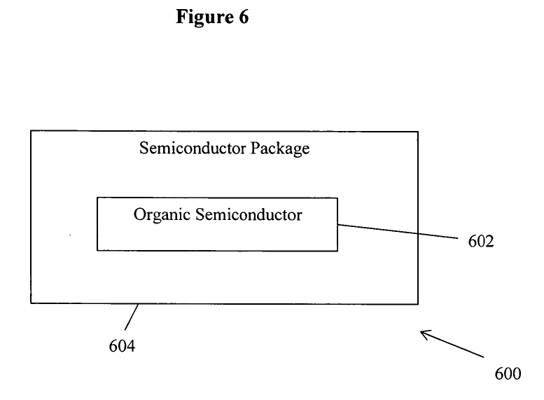

FIG. 6 illustrates a packaged semiconductor device 600. Semiconductor device 600 includes an organic semiconductor 602 packaged in a semiconductor package 604. According to an exemplary embodiment of the present invention, hydrostatic pressure can be applied to organic semiconductor 602 in package 604. The pressure applied is sealed into package 604. The hydrostatic pressure may be a positive pressure (i.e., compressive) in comparison to atmospheric pressure, or may be a negative pressure (i.e., a vacuum). The hydrostatic pressure may be applied to package 604 through a number of exemplary mechanisms, including, but not limited to, gaseous pressure, liquid pressure, gel pressure, solid pressure, or a combination of these mechanisms. By applying the hydrostatic pressure to organic semiconductor 602 in package 604, carrier mobility of organic semiconductor 602 may be affected.

For example, the hydrostatic pressure applied may directly alter the carrier mobility through application of the pressure to organic semiconductor 602. In such an embodiment, a positive hydrostatic pressure that results in a compressive force being applied to organic semiconductor 602 may desirably increase carrier mobility of organic semiconductor 602. Alternatively, a negative hydrostatic pressure that results in tensile force being applied to organic semiconductor 602 may desirably decrease carrier mobility of organic semiconductor 602.

Further, the hydrostatic pressure may apply a mechanical force to a substrate in package 604 (the substrate is not shown in FIG. 6), where the mechanical force changes a dimension of the substrate, thereby changing the carrier mobility of organic semiconductor 602 mounted on the substrate, as described above. Further still, the hydrostatic pressure may change the carrier mobility of organic semiconductor 602 through both of these methods (i.e., through (a) direct application of pressure to organic semiconductor 602, and (b) application of stress or strain to organic semiconductor 602 through an interface between organic semiconductor 602 and a substrate that supports organic semiconductor 602).

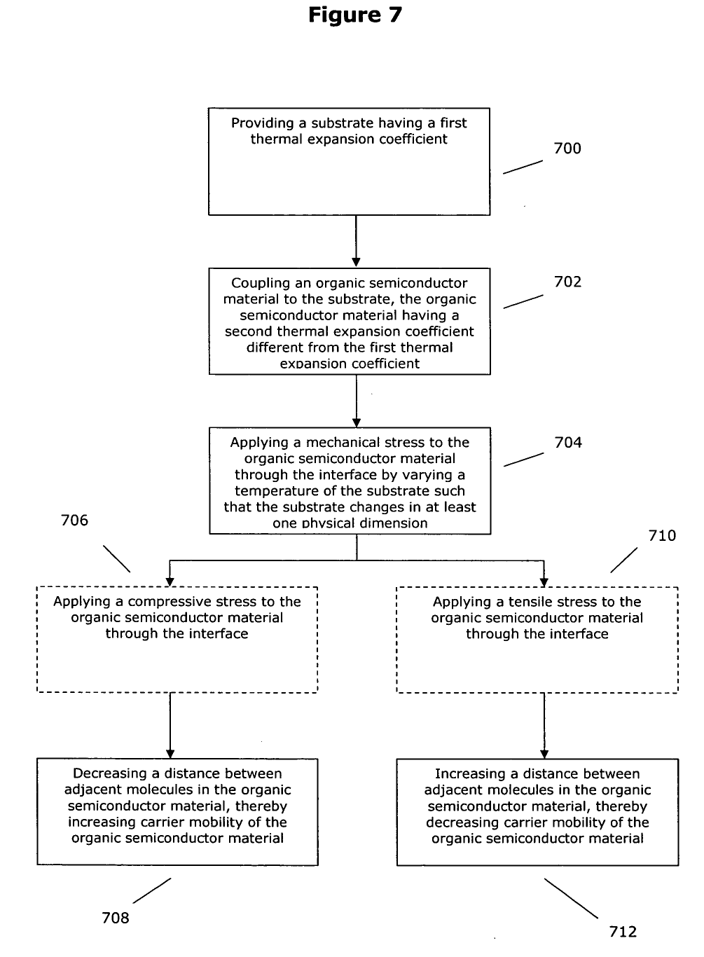

FIG. 7 is a flow diagram illustrating a method of fabricating a semiconductor device. At step 700, a substrate having a first thermal expansion coefficient is provided. At step 702, an organic semiconductor material is coupled to the substrate at an interface between the two components. The organic semiconductor material has a second thermal expansion coefficient that is different from the first thermal expansion coefficient. At step 704, a mechanical stress is applied to the organic semiconductor material through the interface by varying a temperature of the substrate such that the substrate changes in at least one physical dimension. As utilized in this document, the expression “varying a temperature” may refer to an intentional variation in temperature (e.g., heating, cooling) or may refer to a natural normalization to an environmental or ambient temperature.

If the stress applied at step 704 is a compressive stress, the method proceeds through step 706 to step 708, where a distance between adjacent molecules in the organic semiconductor material is decreased, thereby increasing carrier mobility of the organic semiconductor material. If the stress applied at step 704 is a tensile stress, the method proceeds through step 710 to step 712, where a distance between adjacent molecules in the organic semiconductor material is increased, thereby decreasing carrier mobility of the organic semiconductor material.

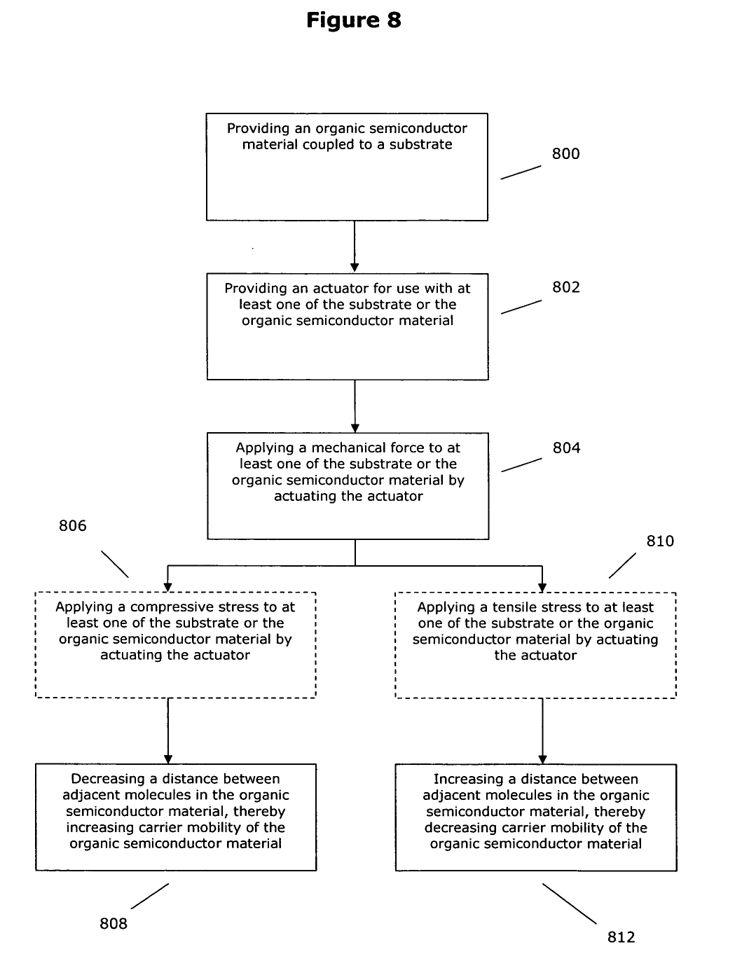

FIG. 8 is a flow diagram illustrating another method of fabricating a semiconductor device. At step 800, an organic semiconductor material coupled to a substrate is provided. At step 802, an actuator for use with at least one of the substrate or the organic semiconductor material is provided. The actuator is selected from the group comprising piezoelectric actuators, piezomagnetic actuators, magnetostrictive actuators, shape memory alloy actuators, magnetic shape memory alloy actuators, and electroactive polymer actuators. At step 804, a mechanical force is applied to at least one of the substrate or the organic semiconductor material by actuating the actuator. The mechanical force applied by actuating the actuator varies a carrier mobility of the organic semiconductor material.

If the mechanical force applied at step 804 is a compressive stress, the method proceeds through step 806 to step 808, where a distance between adjacent molecules in the organic semiconductor material is decreased, thereby increasing carrier mobility of the organic semiconductor material. If the mechanical force applied at step 804 is a tensile stress, the method proceeds through step 810 to step 812, where a distance between adjacent molecules in the organic semiconductor material is increased, thereby decreasing carrier mobility of the organic semiconductor material.

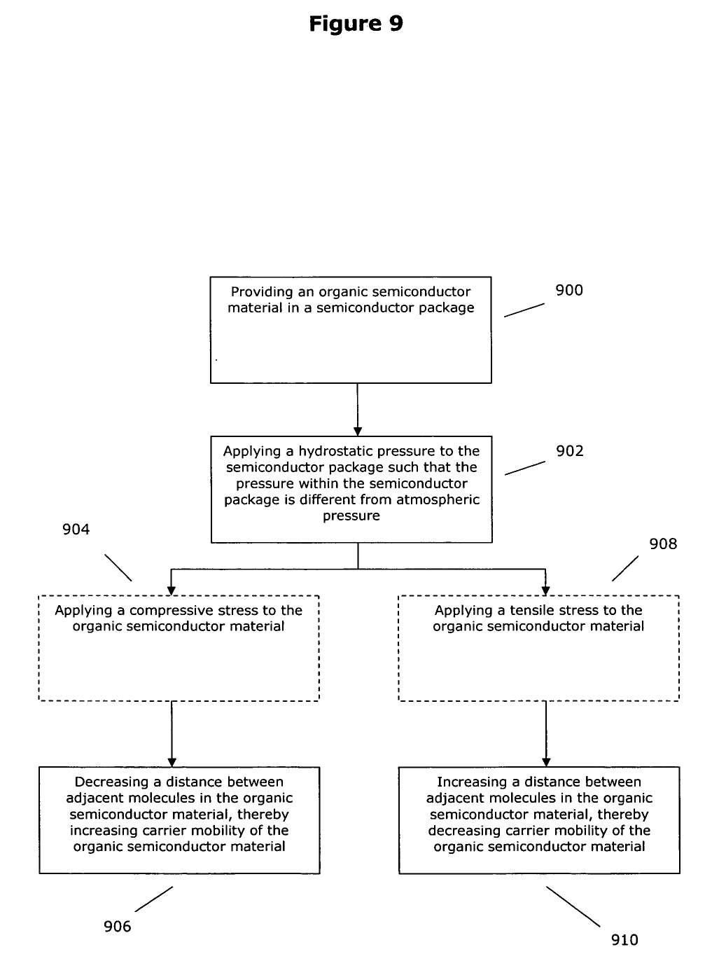

FIG. 9 is a flow diagram illustrating a method of fabricating a semiconductor device. At step 900, an organic semiconductor material in a semiconductor package is provided. At step 902, a hydrostatic pressure is applied to the semiconductor package such that the pressure within the semiconductor package is different from atmospheric pressure. The applied hydrostatic pressure varies a carrier mobility of the organic semiconductor material.

If the hydrostatic pressure results in a compressive stress being applied to the organic semiconductor material, the method proceeds through step 904 to step 906, where a distance between adjacent molecules in the organic semiconductor material is decreased, thereby increasing carrier mobility of the organic semiconductor material. If the hydrostatic pressure results in a tensile stress being applied to the organic semiconductor material, the method proceeds through step 908 to step 910, where a distance between adjacent molecules in the organic semiconductor material is increased, thereby decreasing carrier mobility of the organic semiconductor material.

Through the various exemplary embodiments of the present invention described herein, application of a compressive stress to the organic semiconductor has primarily been described in connection with an increase in carrier mobility. Likewise, application of a tensile stress to the organic semiconductor has primarily been described in connection with a decrease in carrier mobility. However, the present invention is not limited thereto. For example, application of a compressive stress to the organic semiconductor (either directly or through a substrate) may result in a decrease in carrier mobility. Likewise, application of a tensile stress to the organic semiconductor (either directly or through a substrate) may result in an increase in carrier mobility. This result may be achieved, for example, based on a phase transformation or a change in the physical configuration (e.g., morphology) of the organic semiconductor material as a result of the compressive/tensile stress.

The substrate utilized in connection with the present invention may be any of a number of types of substrate including, for example, a plate substrate, wire substrate, spherical substrate, cubical substrate, and the like.

As described in this document, according to certain exemplary embodiments of the present invention, it is desirable that the substrate may be dimensionally altered by varying temperature. In order to further this objective, the substrate may be made of organic materials (e.g., Lexan® resin, a high-performance polycarbonate available from GE Plastics). Lexan® resin has been demonstrated to shrink in the range of 10-500 ppm, and even up to 1000 ppm, through thermal treatment. This level of shrinkage may desirably be used to apply stress to the organic semiconductor.

Although the device structures and fabrication methods described in this document depict direct connections between the various components of a semiconductor device (e.g., a direct connection between a substrate and an organic semiconductor, a direct connection between an actuator and either of a substrate or an organic semiconductor, etc.), the present invention is not limited to such direct configurations. The inventive concepts disclosed may be applied to a diverse set of device structures and fabrication methods. For example, insulative layers, electrical connections, and other elements may be provided between the various structural components. Thus, as used in this document, the term “coupling” does not necessarily refer to a direct connection; rather, the term may apply to any connection that facilitates the desired mechanical interaction and ultimate shift in carrier mobility of the organic semiconductor material.

The inventive concepts may be applied to a broad range of traditional and non-traditional semiconductor applications. More specifically, the concepts disclosed in this document are suitable to any application utilizing organic semiconductor materials.

Although the invention is illustrated and described above with reference to specific embodiments, the invention is not intended to be limited to the details shown. Rather, various modifications may be made in the details within the scope and range of equivalents of the claims and without departing from the invention.

What is claimed:

1. A semiconductor device comprising:
a substrate having a first thermal expansion coefficient; and
an organic semiconductor material coupled to the substrate at an interface therebetween, the organic semiconductor material having a second thermal expansion coefficient that is different from the first thermal expansion coefficient;
wherein:
a difference between the first thermal expansion coefficient and the second thermal expansion coefficient causes a tensile stress in a plane parallel to the interface to be transferred from the substrate to the organic semiconductor material through the interface; and
the tensile stress in the plane parallel to the interface causes compression of the organic semiconductor material in a direction normal to the interface.

2. The semiconductor device of claim 4 wherein the compression of the organic semiconductor material in a direction normal to the interface decreases a distance between adjacent molecules in the organic semiconductor material, thereby increasing carrier mobility of the organic semiconductor material.

3. A method of fabricating a semiconductor device comprising:
providing a substrate having a first thermal expansion coefficient;
coupling an organic semiconductor material to the substrate at an interface therebetween, the organic semiconductor material having a second thermal expansion coefficient different from the first thermal expansion coefficient; and
applying a mechanical stress to the organic semiconductor material through the interface by varying a temperature of the substrate such that the substrate changes in at least one physical dimension.

4. The method of claim 3 wherein the applying step includes applying a tensile stress to the organic semiconductor material through the interface.

5. The method of claim 4 further comprising the step of decreasing a distance between adjacent molecules in the organic semiconductor material, thereby increasing carrier mobility of the organic semiconductor material.
